(19) United States
(12) Patent Application Publication
(10) Pub. No.: US 2020/0105800 A1
(43) Pub. Date: Apr. 2, 2020

(54) DRIVER CIRCUIT AND MANUFACTURING METHODS THEREOF FOR DISPLAY DEVICES

(71) Applicant: Kunshan Go-Visionox Opto-Electronics Co., Ltd., Kunshan (CN)

(72) Inventors: Jinfang ZHANG, Kunshan (CN); Lu ZHANG, Kunshan (CN); Zhenzhen HAN, Kunshan (CN); Siming HU, Kunshan (CN); Xiangqian WANG, Kunshan (CN); Qinggang LIU, Kunshan (CN); Hui ZHU, Kunshan (CN)

(21) Appl. No.: 16/326,912

(22) PCT Filed: Apr. 25, 2018
(86) PCT No.: PCT/CN2018/084519

§ 371 Date: Feb. 20, 2019

(30) Foreign Application Priority Data
Jun. 20, 2017 (CN) 201710471810.9

(51) Int. Cl. H01L 27/12; H01L 21/66; H01L 23/60; G01R 31/28

(52) U.S. Cl. CPC H01L 27/1244; H01L 22/34; G01R 31/2825; H01L 27/1262; H01L 23/60

(57) ABSTRACT

A driving circuit board (10), a method for manufacturing the same, and a display device (30) are disclosed. The driving circuit board includes a substrate (100), a test circuit (200) and two connecting units (210) disposed on the substrate. The two connecting units are disposed on both sides of the test circuit respectively. The driving circuit board further includes a protective layer (300) disposed over the upper surface of the test circuit and covering the test circuit. By providing the protective layer, the purpose of preventing the test circuit line from being corroded or damaged can be achieved.

### FIELD

The present disclosure relates to a field of displays.

### BACKGROUND

A mounting circuit is provided in a substrate non-display region of a screen body of a display device. The mounting circuit generally includes an input pad and an output pad disposed oppositely, with a bare test circuit disposed between the input pad and the output pad. An input pin and an output pin of the integrated circuit chip are connected to the input pad and the output pad respectively, so that the integrated circuit chip is electrically connected to the substrate.

The test circuit is easily damaged and particularly easy to be electrostatically broken down. After the test circuit is damaged, it may cause an error judgment as to whether the screen body is qualified. This is quite disadvantageous for the production of the screen body.

### SUMMARY

Based on the above, regarding the problem that the test circuit of circuit substrate is easily damaged, it is needed to provide a driving circuit board and a display device.

According to one aspect of the present invention, a driving circuit board is provided. The driving circuit board includes a substrate, a test circuit disposed on the substrate, and a protective layer disposed on an upper surface of the test circuit and covering the test circuit.

In the driving circuit board according to the above aspect of the present invention, the test circuit is covered by the protective layer. In this way, static electricity accumulation on the driving circuit can be avoided, thereby avoiding the thin film transistor of the test circuit being broken down. In this way, the test circuit is in an undamaged state, avoiding adverse effects on the screen test result caused by the damage of the test circuit, which facilitates the production of the screen body.

In one of the embodiments, the protective layer is made of organic material.

The protective layer made of an organic material has an adhesive property, which facilitates the covering and fixing of the protective layer to the surface of the test circuit. The strength property of the organic material prevents the test circuit from being damaged by external stress.

In one of the embodiments, an upper surface of the protective layer includes a rough region.

The rough region may increase a pasting area when the integrated circuit chip is pasted with the protective layer, and at the same time, the adhesion between the integrated circuit chip and the protective layer can be enhanced.

In one of the embodiments, the rough region is any one or a combination of corrugation structure, a plurality of protrusions, a plurality of pits, staggered with other and a mesh.

The combination of a plurality of structures can flexibly increase the area of the protective layer when pasting, so as to enhance the firmness of the pasting. The pits, the protrusions, or the corrugations can enhance adhesion between the integrated circuit chip and the protective layer.

In one of the embodiments, an upper surface of the protective layer further includes a planar region located at a central region of the upper surface, and the rough region surrounds the planar region.

When pasting the integrated circuit chip on the surface of the protective layer, more conductive adhesive is applied around the protective layer, while a small amount of conductive adhesive is applied in the planar region of the protective layer. In this way, not only can the integrated circuit chip be fixed, but also the central region of the gate corresponding to the protective layer can be prevented from being excessively pressed downward.

In one of the embodiments, the driving circuit board further includes a display region thin film transistor array disposed on the substrate and having a planarization layer, and the protective layer is integrally formed with the planarization layer of the display region of the thin film transistor array.

Forming the protective layer integrally with the planarization layer of the thin film transistor array in the display region can reduce processes and improve work efficiency.

In one of the embodiments, the protective layer is made of inorganic material.

Inorganic materials have a certain strength, with certain wear resistance compressive resistance performances.

In one of the embodiments, the substrate is further provided with at least one connecting unit adjacent to the test circuit. The test circuit may transmit a test signal to the screen body through the connecting unit.

In one of the embodiments, the substrate is further provided with two connecting units located respectively on both sides of the protective layer. Preferably, the two connecting units are disposed symmetrically on two sides of the protective layer.

In one of the embodiments, the test circuit and the connecting unit are located within a non-display region of the substrate; on either side of the test circuit, a distance from an edge of the non-display region of the substrate to one side of the connecting unit is equal to a distance from another side of the connecting unit to a side of the protective layer close to the connecting unit.

The equidistant arrangement of the connecting unit and the protective layer can maintain the stress uniformity of the substrate, and the problem of imbalance stress on the integrated circuit chip when it is crimped may be avoided.

According to another aspect of the present invention, a display device is provided. The display device includes a driving circuit board, the driving circuit board including: a substrate including a non-display region and a display region; a test circuit disposed on the substrate and located within the non-display region; a protective layer disposed on an upper surface of the test circuit and covering the test circuit; and a display region thin film transistor array disposed within the display region. The test circuit is electrically connected with the display region thin film transistor array.

Thanks to the protective layer provided on the surface of the test circuit, the test circuit can have reliable operating performance, and the use of the display device will not be affected by the damage of the test circuit when the display device is in normal use, and thus the display device has a longer lifetime.

### BRIEF DESCRIPTION OF THE DRAWINGS

FIG. 1 is a structural schematic diagram of a display device according to an embodiment of the present invention.

FIG. 2 is a cross section schematic diagram of a driving circuit board according to an embodiment of the present invention.

FIG. 3 is a schematic diagram illustrating the positional relationship between a protective layer and a connecting unit in a driving circuit board according to an embodiment of the present invention.

FIG. 4 is a structural schematic diagram of a surface of a protective layer according to an embodiment of the present invention.

FIG. 5 is a structural schematic diagram of a surface of a protective layer according to another embodiment of the present invention.

FIG. 6 is a structural schematic diagram of a corrugated surface of a protective layer according to an embodiment of the present invention.

### DETAILED DESCRIPTION OF THE INVENTION

In order to make the purpose, technical scheme and technical effect of the invention more clear, the specific embodiments of the present invention are described below with reference to the accompanying drawings. It is to be understood that the specific embodiments described herein are merely used to illustrate the invention and are not intended to limit the invention.

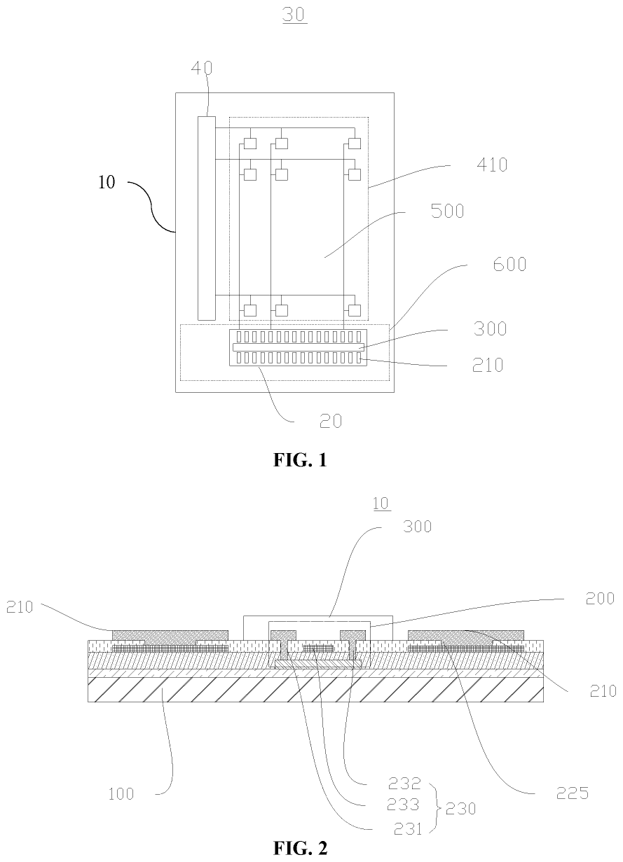

FIG. 1 illustrates a display device 30 according to one embodiment of the present invention. As shown in FIG. 1, the display device 30 includes a driving circuit board 10, and a data driving circuit 20, a scan driving circuit 40, and a display region thin film transistor array 410 provided on the driving circuit board 10. The display region thin film transistor array 410 is electrically connected to the data driving circuit 20 and the scan driving circuit 40. The data driving circuit 20 and the scan driving circuit 40 can control the operation of the display region thin film transistor array 410. The driving circuit board 10 includes a display region 500 and a non-display region 600. The display region thin film transistor array 410 is located in the display region 500. The non-display region 600 includes a protective layer 300 covering a test circuit (not shown), and a pair of connecting units 210 formed on both sides of the protective layer.

FIG. 2 illustrates a driving circuit board 10 according to one embodiment of the present invention. The driving circuit board 10 includes a substrate 100, a test circuit 200 disposed on the substrate 100, and a protective layer 300 disposed on an upper surface of the test circuit 200 and covering the test circuit 200. In conjunction with FIG. 1, the test circuit 200 is disposed in the non-display region 600.

The substrate 100 can be a glass substrate, a flexible plastic substrate, or a substrate made of other organic materials having a certain strength.

In one of the embodiments, the driving circuit board 10 further includes two connecting units 210 disposed in the non-display region 600 of the surface of the substrate 100. The two connecting units 210 are disposed respectively on two sides of the test circuit 200 and adjacent to the test circuit 200. In using, the two connecting units 210 act as an input pad and an output pad of an integrated circuit chip, respectively.

In one embodiment, the integrated circuit chip (not shown) could be electrically connected to the input pad and the output pad through input and output pins. The integrated circuit chip could be disposed above the test circuit 200. In such a way, the integrated circuit chip communicates with the driving circuit board 10 through the input pad, output pad, input pins and output pins, and controls the display device 30. In one embodiment, conductive adhesive is also coated among the input pad, output pad, input pins, and output pins, to therefore enhance an electrical connection among the input pad, output pad, input pins, and output pins, and facilitate the integrated circuit chip to be fixed above the test circuit 200. The specific operating process of the integrated circuit chip is well known to those skilled in the art and will not be described herein.

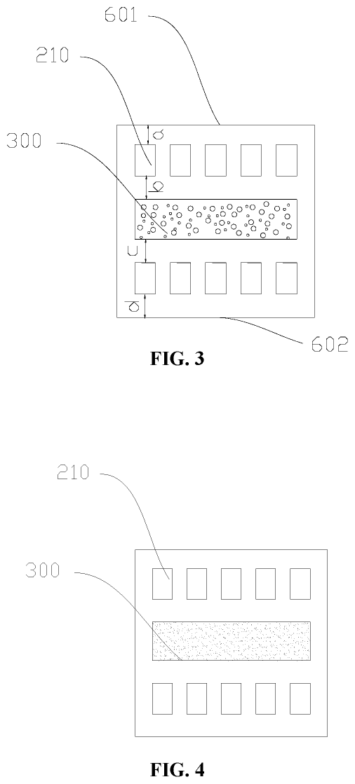

In one of the embodiments, the two connecting units 210 are disposed symmetrically on both sides of the test circuit 200. The symmetric arrangement of the connecting units 210 on both sides of the test circuit 200, the stress generated when the integrated circuit chip is depressed can be balanced, and the effect of the chip being depressed can be ensured, therefore, the service life of the substrate 100 is increased. In one preferred embodiment, as shown in FIG. 3, distances a, d respectively from the edge 601, 602 of the non-display region 600 to corresponding sides of the connecting unit 210 and the distances b, c respectively from the two connecting units 210 to the corresponding edges of the protective layer 300 are equal, i.e., a=b=c=d. The edges 601, 602 of the non-display region 600 could be boundaries of an organic glue layer, preferably formed together with the protective layer 300. It can be understood that the equidistant arrangement of the connecting units 210 and the test circuit 200 could maintain the substrate 100 stressed equably, and therefore, the substrate 100 can be more effectively prevented from being damaged due to non-uniform stress.

The test circuit 200 is used to test whether the display of the screen body is qualified. The test circuit 200 may be configured to test whether communication lines of the screen and/or pixels of the screen are damaged. Referring again to FIG. 2, the test circuit 200 may include a thin film transistor 230 including a source 231, a drain 232, and a gate 233, and an associated circuit. Through the test circuit 200, a test signal can be input to the screen body. The test circuit 200 includes a test unit. The test unit could be connected to the thin film transistor 230 via a plurality of signal channels. The test circuit 200 is used as follows: the test unit supplies a gate-on voltage to the gate 233 to turn on the source 231 and the drain 232, and the thin film transistor 230 is turned on. Then, a test signal is input from the test unit to the screen body via the thin film transistor 230 to test whether the communication lines of the screen body and the display pixels of the screen body are damaged.

In order to ensure that the thin film transistor 230 and the conductive lines in the test circuit 200 are undamaged, when the test circuit 200 has been manufactured, a protective layer 300 covering the test circuit 200 is formed over the test circuit 200. The protective layer 300 is configured to protect the test circuit 200. For example, the test circuit 200 is isolated from the external environment, thereby avoiding accumulating static electricity at the thin film transistor 230 of the test circuit 200, to prevent the thin film transistor 230 from being electrostatically broken down. Electrostatic breakdown can cause damage to the test circuit 200, thereby causing trouble for subsequent work. For example, when the thin film transistor 230 is broken down, the test result of the screen body will be adversely affected and the screen body may be erroneously judged as to whether it is qualified. Further, a more complicated reexamination step is required in a subsequent step to find a qualified screen from the screens being misjudged as unqualified screens. Additionally, the protective layer 300 may protect the test circuit 200 from accidental corrosion so as to ensure normal function of the test circuit 200 during test.

In one embodiment, the protective layer 300 may be made of an organic material or an inorganic material. In one preferred embodiment, the protective layer 300 may be made of a material same to that of the planarization layer of the display region 500. In another embodiment, the protective layer 300 can be made from SiOx film or SiNx film. In the case where the protective layer 300 is formed of organic materials, the protective layer 300 may also have a certain buffering performance, such that the damage to the test circuit 200 caused by excessive stress from the integrated circuit chip on the surface of the test circuit 200 or on the protective layer 300 may be avoided. In one embodiment, the protective layer 300 has a thickness from 1.5 mm to 2 mm. The protective layer 300 with a thickness of 1.5 mm to 2 mm can not only solve the static electricity problem in the test circuit 200, but also has a sufficient buffering performance.

Preferably, the conductive adhesive is disposed between the protective layer 300 and the integrated circuit chip to further fix the integrated circuit chip. In the preferred embodiment shown in FIG. 4, there is a rough region on the surface of the protective layer 300 away from the substrate 100. For example, when the protective layer 300 is formed of organic materials, the rough region or a mesh can be formed by photolithography; when the protective layer 300 is formed of inorganic materials, the rough region can be formed by etching the protective layer 300. In another embodiment, the rough region can be formed by either one or combination of pits, protrusions, arranged densely, gullies or corrugation structures staggered to each other. In fact, the rough region can be constructed in any other suitable forms. The inventors have found that through this configuration, the lower surface of the integrated circuit chip can be bonded or pasted together with the rough region of the protective layer 300 during the integrated circuit chip assembling process. In this way, the rough region may increase the bonding force between the integrated circuit chip and the protective layer 300, so that the integrated circuit chip and the protective layer 300 are firmly attached.

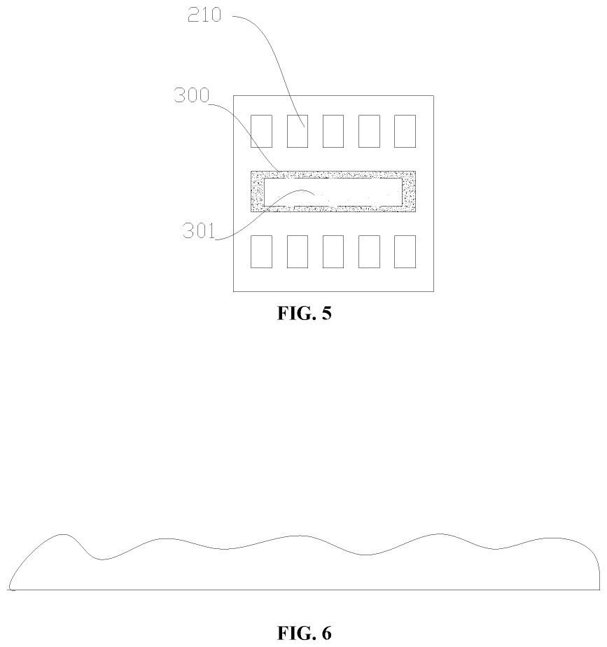

The location of the rough region can be adjusted according to that different locations of the test circuit 200 have different stresses applied on. For example, the rough region can be formed as the entire outer surface of the protective layer 300 or a partial region of the outer surface of the protective layer 300. Preferably, the rough region may be disposed around the protective layer 300. Referring to FIG. 5, in one of the embodiments, the central region of the protective layer 300 is a planar region 301, and the surrounding portion is the rough region. When pasting the integrated circuit chip on the surface of the protective layer 300, a method of more conductive adhesive used around the protective layer 300 and less adhesive used in the planar region 301 of the protective layer 300 can not only well fix the integrated circuit chip, but also prevent the central region of the gate 233 corresponding to the protective layer 300 from being excessively pressed down. In this way, the amount of the conductive adhesive is reduced, and the thin film transistor 230 is protected.

In the embodiment shown in FIG. 6, the rough surface of the outer surface of the protective layer 300 is in corrugation structure. In the case that the protective layer 300 is formed of organic materials, the rough region in the form of corrugation structures is preferable. The reason is that the configuration of the corrugation structures can be relatively gentle, the using amount of conductive adhesive can be reduced, and the purpose of pasting the integrated circuit chip and the protective layer 300 firmly can be achieved.

In one embodiment, the test circuit 200 is electrically connected to circuit of the display region 500. The protective layer 300 covering the surface of the test circuit 200 can prevent the test circuit 200 from being corroded or damaged. During the process of the producing the driving circuit board 10, there are other manufacturing processes after the test circuit 200 is produced. The test circuit 200 can be prevented from being scratched or corroded by other chemical agents in other manufacturing processes, due to the protective layer 300. Therefore, an open circuit phenomenon will not occur in the test circuit 200, and there is no misjudgment caused by the damage of the test circuit when the screen is tested.

The protective layer 300 can be formed in the following way.

When the protective layer 300 and the planarization layer of the display region 500 are made of the same material, the forming process of the protective layer 300 may be: laying a planarization layer on the display region 500 and the non-display region 600; then removing portions of the planarization layer corresponding to two connecting units 210 by etching. In this way, the planarization layer on the test circuit 200 forms the protective layer 300. It can be understood that the rough region on the protective layer 300 can also be formed by means of etching.

When the protective layer 300 is formed of inorganic materials, the protective layer 300 can be formed by depositing a film layer of an inorganic material on the test circuit 200.

The above are embodiments of the disclosure described in detail, and should not be deemed as limitations to the scope of the present disclosure. It should be noted that variations and improvements will become apparent to those skilled in the art to which the present disclosure pertains without departing from its spirit and scope. Therefore, the scope of the present disclosure is defined by the appended claims.

1. A driving circuit board, comprising:
a substrate;
a test circuit disposed on the substrate; and
a protective layer disposed on an upper surface of the test circuit and covering the test circuit.

2. The driving circuit board of claim 1, wherein the protective layer comprises organic material.

3. The driving circuit board of claim 1, wherein an upper surface of the protective layer comprises a rough region.

4. The driving circuit board of claim 3, wherein the rough region is one of or a combination of corrugation structure, a plurality of protrusions, a plurality of pits staggered with other, and a mesh.

5. The driving circuit board of claim 3, wherein the upper surface of the protective layer further comprises a planar region located at a central region of the upper surface of the protective layer, the planar region being surrounded by the rough region.

6. The driving circuit board of claim 1, further comprising a display region thin film transistor array disposed on the substrate and having a planarization layer, the protective layer being integrally formed with the planarization layer of the display region of the thin film transistor array.

7. The driving circuit board of claim 1, wherein the protective layer is made of inorganic material.

8. The driving circuit board of claim 1, wherein the substrate is further provided with at least one connecting unit adjacent to the test circuit.

9. The driving circuit board of claim 8, wherein the substrate is further provided with two connecting units located on two sides of the protective layer.

10. The driving circuit board of claim 9, wherein the two connecting units are disposed symmetrically on both sides of the protective layer.

11. The driving circuit board of claim 8, wherein the test circuit and the connecting units are located within a non-display region of the substrate; on either side of the test circuit, a distance from an edge of the non-display region of the substrate to one side of the connecting unit is equal to a distance from another side of the connecting unit to a side of the protective layer close to the connecting unit.

12. A display device, comprising:
a driving circuit board, including:
a substrate including a non-display region and a display region;
a test circuit disposed on the substrate and located within the non-display region;
a protective layer disposed on an upper surface of the test circuit and covering the test circuit; and
a display region thin film transistor array disposed within the display region;
wherein the test circuit is electrically connected with the display region thin film transistor array.

13. A method for manufacturing a driving circuit board, comprising:
providing a substrate;
disposing a test circuit and a pair of connecting units on the substrate; and
disposing a protective layer on an upper surface of the test circuit and covering the test circuit.

14. The method of claim 13, wherein the protective layer and the planarization layer of the display region comprise a same material,
the disposing a protective layer on an upper surface of the test circuit comprising:
laying a planarization layer on the driving circuit board;
removing portions of the planarization layer corresponding to the two connecting units by etching; and
making the planarization layer on the test circuit forms the protective layer.

15. The method of claim 13, wherein the protective layer comprises inorganic materials, the protective layer being formed by depositing a film layer of an inorganic material on the test circuit.
